(19) United States
(12) Patent Application Publication
(10) Pub. No.: US 2003/0051908 A1
(43) Pub. Date: Mar. 20, 2003

(54) Dram module package

(76) Inventor: Kai-Kuang Ho, Feng-Shan City (TW)

Correspondence Address: J.C. Patents, Inc., Suite 250, 4 Venture, Irvine, CA, 92618, US

(21) Appl. No.: 09/967,714

(22) Filed: Sep. 27, 2001

(30) Foreign Application Priority Data
Sep. 19, 2001 (TW) 90122965

(51) Int. Cl. H05K 7/06

(52) U.S. Cl. 174/260; 174/256; 174/257; 174/258; 174/259; 257/723; 257/787

(57) ABSTRACT

A DRAM module package, which uses a board on chip (BOC) manner to form multiple windows on the module printed circuit board (PCB). A chip is directly adhered to a backside of the module PCB and the bonding pads of the chip are arranged to be located at a center of the windows. The conductive wire penetrates through the window and connects crossing between a mounting pad in front of the module PCB and the bonding pad of the chip. Then, an encapsulation process is performed to protect the conductive wires, the mounting pads on the module PCB, the chip and the bonding pads.

### CROSS-REFERENCE TO RELATED APPLICATION

This application claims the priority benefit of Taiwan application serial no. 90122965, filed Sep. 19, 2001

### BACKGROUND OF THE INVENTION

1. Field of the Invention

The invention relates in general to a DRAM module package, and more particularly, to a dynamic random access memory (DRAM) module package using a direct chip attach (DCA) method to attach a chip on a module printed circuit board (PCB) directly with a type of board on chip (BOC).

2. Description of the Related Art

In semiconductor circuit products that do not require very high pin counts, wire bonding is often used to electrically connect the bonding pads on a chip to leads of a lead frame. Such products include the small outline package (SOP) and the quad flat package4 (QFP). The distribution of the pads on the chip includes the peripheral pads and the central pads

The DRAM chip requires a lower pin count and has simple internal circuits, so that the pads can be designed as the central pads to share a part of the interconnection. The conventional DRAM module normally adapts the surface mount technology (SMT) to fix the packaged chip on a module PCB.

To simplify the process, the direct chip attach method is used before encapsulation to attach the rear surface of the chip onto the surface of the module PCB. The wire bonding method is further used to form conductive wires connecting the pads on the active surface of the chip with the terminals on the surface of the module PCB. The encapsulation is then performed to complete the package of the DRAM module with a type of chip on board (COB).

Referring to FIGS. 1 and 2, FIG. 1 shows a conventional DRAM module, and FIG. 2 shows an enlarged view of the local area 100 in FIG. 1 In FIG. 1, several DRAM devices 102 are arranged on the module PCB 104 For the convenience of description, FIG. 2 does not illustrate the molding compound applied on the exterior of the DRAM 102. The bonding pads 106 are distributed on a center of the chip 108. Via the conductive wires 110, the bonding pads 106 are electrically connected to the mounting pads 112 on the module PCB 104 at two sides of the chip 108.

Referring to FIG. 3, a local cross-sectional view of FIG. 1 is shown. The chip has an active surface 108a and a rear surface 108b opposite the active surface 108a Using a tape 102, the rear surface 108b of the chip 108 is attached to a top surface 104a of the module PCB 104. Using the wire bonding technique, the conductive wires 110 are connected between the bonding pads 106 of the chip 108 and the mounting pads 112 on the module PCB 104. A molding compound 114 is then applied to enclose the chip 108, the conductive wires 110, the mounting pads 112 and a part of the module PCB 104. In this manner of chip on board, COB, the chip 108 can thus be assembled on the module PCB 104 directly.

As mentioned above, as the bonding pads 106 of the chip 108 is the central distribution type, the longer distance for the bonding wires is longer than the peripheral bonding pads. Problems caused by overlong conductive wires 110 thus occur. In addition, the collapsed long conductive wires easily contact the edge of the chip 108, so that a short circuit problem (short to chip edge) is caused.

### SUMMARY OF THE INVENTION

The invention shortens the conductive wires of the DRAM module, so that the resistance of the conductive wires is effectively reduced, and the operation performance of the DRAM is very much enhanced. Further, the short to chip edge problem caused by overlong conductive wires in the prior art can also be resolved

Accordingly, the invention provides DRAM module package including a module PCB. The module PCB having a top surface and an opposing bottom surface comprises several windows penetrating through the module PCB. A module circuit is located in the module PCB. The module circuit includes several internal mounting pads and several external mounting pads. The internal mounting pads are located on the top surface of the module PCB, and the external mounting pads are located on a side of the module PCB. The internal mounting pads are electrically connected to each, and also to the external mounting pads. Each of a plurality of chips comprises an active surface and several bonding pads, which are located at approximately the center of the corresponding active surface. One chip corresponds to one window and has the active surface thereof attached to the bottom surface of the module PCB, and the bonding pads are substantially positioned at the center of the window. In addition, several conductive wires are connected to the bonding pads and the internal mounting pads through the window. Several molding compounds are used to cover the corresponding die, internal mounting pads, bonding pads, conductive wires and a part of the module PCB.

In the invention, the internal mounting pads of the module PCB is closer to the bonding pads at the center of the active surface, so that the conductive wires are greatly reduced. The resistance is greatly reduced to enhance the performance of the DRAM module.

The invention reduces the length of the conductive wires connecting between the bonding pads of the chip and the mounting pads of the module PCB, so that the problem of short to chip edge is resolved

Both the foregoing general description and the following detailed description are exemplary and explanatory only and are not restrictive of the invention, as claimed.

### BRIEF DESCRIPTION OF THE DRAWINGS

FIG. 1 shows the conventional DRAM module;

FIG. 2 shows an enlarged view of a local area 100 of FIG. 1;

FIG. 3 shows a local cross-sectional view of FIG. 1;

FIG. 4 shows an embodiment of a DRAM module in the invention;

FIG. 5 shows an enlarged cross-sectional view of a local area 200 in FIG. 4;

FIG. 6 shows a local cross-sectional view of FIG. 4; and

FIGS. 7A to 7D are cross-sectional views showing the packaging process of the DRAM module according to the invention.

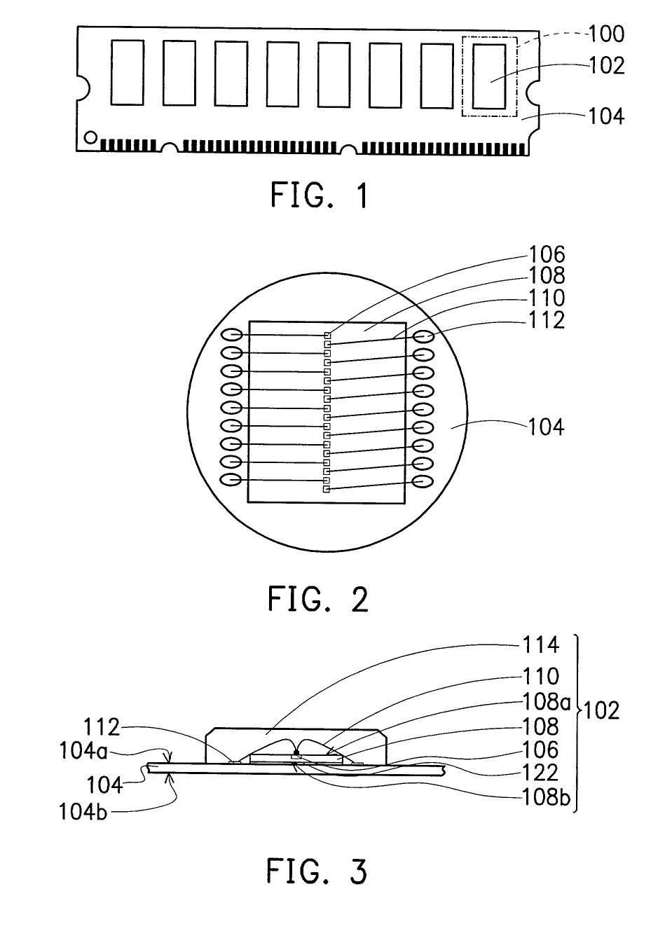

### DESCRIPTION OF THE PREFERRED EMBODIMENTS

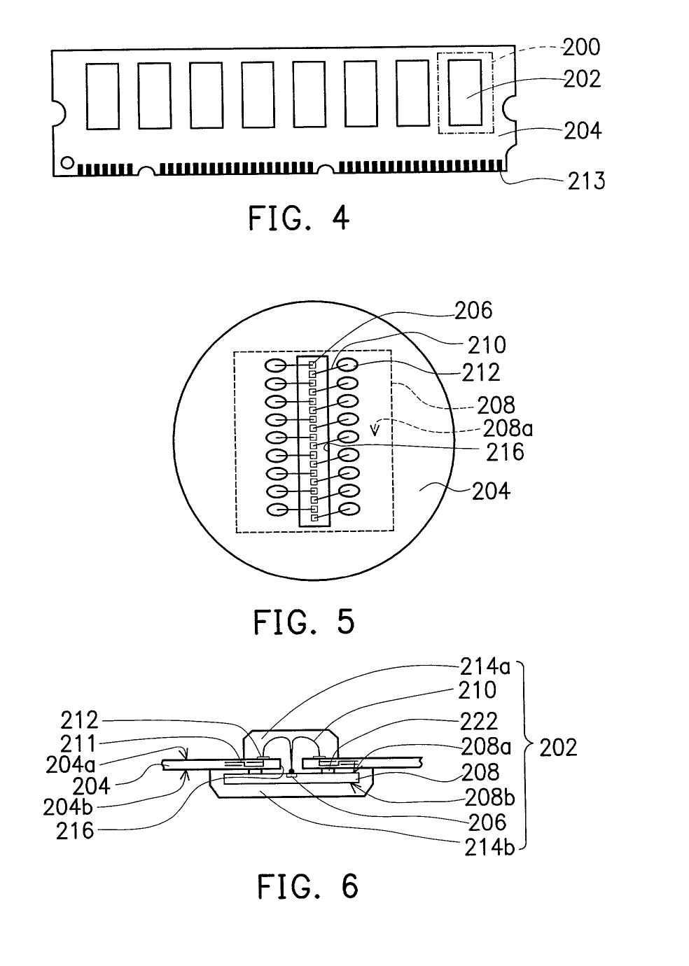

Referring to FIGS. 4 and 5, FIG. 4 shows an embodiment of a DRAM module and FIG. 5 shows an enlarged view of the local area 200 in FIG. 4. In FIG. 4, a plurality of DRAM devices 202 is arranged on the module printed circuit board (PCB) 204 For the convenience of description, the molding compounding is not illustrated in FIG. 5. The module PCB 204 has a plurality of windows 216 penetrating through the module PCB 204. A chip 208, for example, a DRAM chip, has bonding pads 206 distributed on the center of an active surface 208a thereof and the center of the windows 216. Conductive wires 210 are used to connect between the bonding pads 206 of the chip 208 and the mounting pads 204 on the module PCB. The electric connection between the bonding pads 206 and the corresponding mounting pads 212 is thus established

In FIG. 6, the local cross-sectional view is illustrated. The module PCB 204 has a top surface 204a and a bottom surface 208b. The chip 208 has the active surface 208a and an opposing rear surface 208b. In addition, the bonding pads 206 are distributed on the center of the active surface 208a. The inside of the module PCB 204 has a module circuit 211 to electrically connect each chip 208. The module circuit 211 has a plurality of internal mounting pads 212 and a plurality of external mounting pads 213 (as shown in FIG. 4). The internal mounting pads 212 are located on the top surface 204a of the module PCB in response to the bonding pads 206. The internal mounting pads 212 are electrically connected to each other. The external mounting pads 213 are located at one side of the module PCB 204 and electrically connected to the internal mounting pads 212. A tape 222 is used to attach the active surface 208a of the chip 208 to the bottom surface 204b of the module PCB 204. In addition, conductive wires 210 through the windows 216 are formed to connect between the bonding pads 206 of the chip 208 and the internal mounting pads 212 of the module PCB 204. A top molding compound 214a and a bottom molding compound 214b are applied to cover the chip 208, the conductive wires 210, the internal mounting pads 212 and a part of the module PCB 204. Thus, the chip 208 is directly assembled to the module PCB 204 to complete the packaging process on the DRAM module under a type of board on chip (BOC).

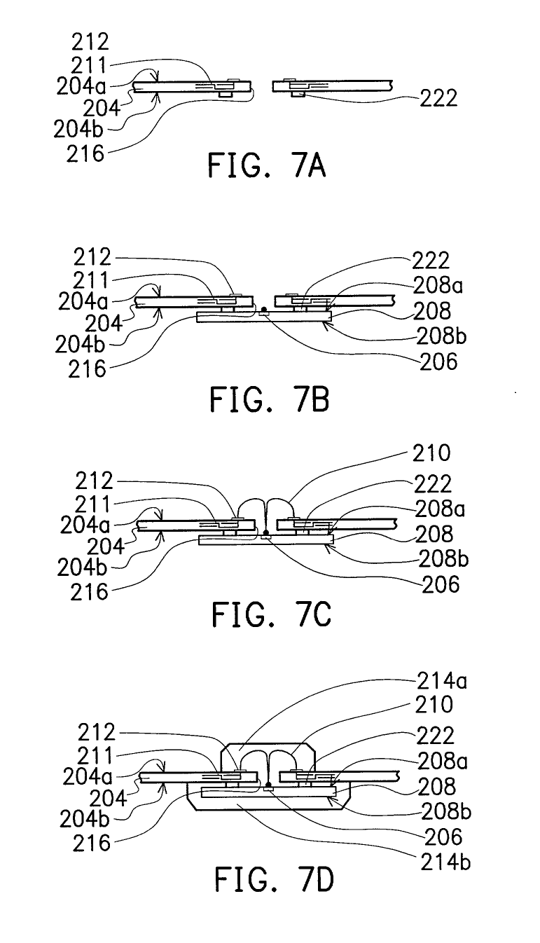

To further describe the DRA module in details, please refer to FIGS. 7A to 7D which are cross-sectional views of the DRAM module package in FIG. 6 In FIG. 7A, a module PCB 204 is formed. For example, the module PCB 204 is made of glass epoxy such as FR-4, FR-5 substrates, or BT substrate made of bismaleimide-triazine (BT) resin. The module PCB 204 has a top surface 204a and a bottom surface 204b. A window 216 is formed to penetrate through the module PCB 204.

A module circuit 211 that has several internal mounting pads 212 and external mounting pads 213 (as shown in FIG. 4) is designed in the module PCB204. The internal mounting pads 212 are located on the top surface 204a and electrically connected to each other. The external mounting pads 213 are located on a side of the module PCB 204 to electrically connect to the internal mounting pads 212. A tape 222 is attached on the bottom surface 204a of the module PCB 204 with respect to two sides of the window 216, so as to attach the active surface 208a of a chip 208 subsequently. The tape 222 can be replaced with a thermal glue.

In FIG. 7B, the chip 208 has the active surface 208a and a rear surface 208b opposing the active surface 208a A plurality of bonding pads 206 is distributed on the center of the active surface 208a. The internal mounting pads 212 on the module PCB 204 are in response to the bonding pads 206. Using the tape 222, the active surface 208a of the chip 208 is adhered to the bottom surface 204b of the module PCB 204 with the bonding pads 206 located at the center of the window 216. An operation temperature is then controlled to between about 150° C. and about 200° C. to cure the tape 222. Preferably, the operation temperature is about 170° C.

In FIG. 7C, a high frequency bonder is used to form conductive wires 210 by wire bonding technique. The conductive wires 210 include gold wires, for example. The conductive wires 210 penetrate through the window 216 to connect the bonding pads 206 of the chip 208 and the internal mounting pads 212 of the module PCB 204. The operation temperature is controlled to between about 100° C. and about 150° C., and preferably is about 120° C.

In FIG. 7D, a molding or coating process is used to encapsulate the active surface 208a and the rear surface 208b using a top molding compound 214a and a bottom molding compound 214b, respectively. A curing step is then performed on the top and bottom molding compound 214a and 214b. The top molding compound 214a encapsulates the conductive wires 210, the internal mounting pads 212, the active surface 208a of the chip 208 and a part of the module PCB 204. The bottom molding compound 214b encapsulates the rear surface 208b and a part of the module PCB 204 The material for forming the top and bottom molding compounds 214a and 214b includes epoxy. Thus, the chip 208 is directly attached on the module PCB 204 to complete a packaging process on the DRAM module by the board on chip, BOC, manner.

Accordingly, the invention shortens the distance between the internal mounting pads of the module PCB and the bonding pads of the die, so that the conductive wires connected therebetween are effectively shortened The performance of the DRAM module is greatly enhanced since the resistance of the conductive wires is reduced.

As the conductive wires across the bonding pads of the chip and the internal mounting pads of the module PCB are shortened, the short to chip edge problem caused by overlong conductive wires is resolved.

The invention has at least the following advantages:

(1) With the design of the window perforating through the module PCB, the internal mounting pads of the module PCB are closer to the bonding pads of the module PCB to reduce the length of the conductive wires. The resistance is reduced, and the performance of the DRAM module is enhanced.

(2) The DRAM module package provided in the invention attaches the DRAM chip with centrally distributed bonding pads on the PCB directly, and shortens the length of the conductive wires connecting the bonding pads of the chip and the internal mounting pads of the PCB. The short to chip edge caused by overlong conductive wire is resolved.

Other embodiments of the invention will appear to those skilled in the art from consideration of the specification and practice of the invention disclosed herein It is intended that the specification and examples be considered as exemplary only, with a true scope and spirit of the invention being indicated by the following claims.

What is claimed is:

1. A dynamic random access memory module package, comprising at least
a module printed circuit board, with a top surface and a bottom surface, the module printed circuit board having a plurality of windows perforating therethrough, and a module circuit with a plurality of internal mounting pads and a plurality of external mounting pads, wherein the internal mounting pads are located on the top surface and electrically connected to each other and to the external mounting pads;
a plurality of chips, each of which has an active surface and a plurality of bonding pads, wherein the bonding pads of each chip are positioned in a corresponding window, and the chips are attached to the printed circuit board with the active surface facing the bottom surface, so that the bonding pads are located in a center of the corresponding window;
a plurality of conductive layers, perforating through the windows to connect the bonding pads and the internal mounting pads; and
a plurality of molding compounds to encapsulate the chips, the internal mounting pads, the bonding pads, the conductive wires and a part of the module printed circuit board.

2. The dynamic random access memory module package according to claim 1, wherein a material of the module printed circuit board includes glass epoxy.

3. The dynamic random access memory module package according to claim 1, wherein a material of the module printed circuit board includes bismaleimide-triazine.

4. The dynamic random access memory module package according to claim 1, wherein the chips include dynamic random access memory chips.

5. The dynamic random access memory module package according to claim 1, wherein the chips are attached to the module printed circuit board using a tape.

6. The dynamic random access memory module package according to claim 1, wherein the chips are attached to the module printed circuit board using a thermal glue.

7. The dynamic random access memory module package according to claim 1, wherein the conductive wires include gold wires.

8. The dynamic random access memory module package according to claim 1, wherein the molding compounds include epoxy.

9. A memory module package, comprising:
a printed circuit board, having a plurality of windows perforating through the printed circuit board and a module circuit with a plurality of internal mounting pads and a plurality of external mounting pads, wherein the internal mounting pads are electrically connected to each other and the external mounting pads,
a plurality of chips, each corresponding to one of the windows, wherein the chips are attached to the printed circuit board and electrically connected to corresponding internal mounting pads; and
a plurality of molding compounds to encapsulate the chips, the internal mounting pads and a part of the printed circuit board.

10. The memory module package according to claim 9, wherein the printed circuit board comprises glass epoxy

11. The dynamic random access memory module package according to claim 9, wherein a material of the module printed circuit board includes bismaleimide-triazine.

12. The dynamic random access memory module package according to claim 9, wherein the chips include dynamic random access memory chips.

13. The dynamic random access memory module package according to claim 9, wherein the chips are attached to the module printed circuit board using a tape.

14. The dynamic random access memory module package according to claim 9, wherein the chips are attached to the module printed circuit board using a thermal glue.

15. The dynamic random access memory module package according to claim 9, wherein the molding compounds include epoxy
